(19) United States
(12) Patent Application Publication
(10) Pub. No.: US 2007/0290310 A1
(43) Pub. Date: Dec. 20, 2007

(54) Semiconductor Device and Method for Manufacturing the Same

(75) Inventors: Hidetoshi KUSANO, Oita (JP); Tomoshi OHDE, Kanagawa (JP)

Correspondence Address: KATTEN MUCHIN ROSENMAN LLP, 575 MADISON AVENUE, NEW YORK, NY, 10022-2585, US

(73) Assignees: SONY CORPORATION, Tokyo (JP); SONY COMPUTER ENTERTAINMENT INC., Tokyo (JP)

(21) Appl. No.: 11/753,002

(22) Filed: May 24, 2007

(30) Foreign Application Priority Data
Jun. 16, 2006 (JP) 2006-167626

(51) Int. Cl. H01L 23/06

(52) U.S. Cl. 257/684

(57) ABSTRACT

The heat dissipation characteristics of a semiconductor device having a flip-chip mounted semiconductor chip are improved at low costs. The semiconductor device includes: a substrate; the semiconductor chip which is flip-chip mounted on the substrate with the front surface of the chip facing downward; a sealing resin layer which is molded around the semiconductor chip; a phase change portion which is provided on the rear surface of the semiconductor chip so as to be capable of being thermally connected to a heat dissipation member such as a heat sink or a heat pipe. The phase change portion is melted by the operating heat of the semiconductor chip. Therefore, the intimate characteristics between the semiconductor chip and the heat dissipation member are improved, and the heat dissipation characteristics of the semiconductor chip are improved.

### BACKGROUND OF THE INVENTION

1. Field of the Invention

The present invention relates to a semiconductor device and a method for manufacturing the same. More specifically, the invention relates to a semiconductor device having excellent heat dissipation characteristics and a method for manufacturing the same.

2. Description of the Related Art

In recent years, the size of electronic devices such as computers, cellular phones, and PDAs (Personal Digital Assistances) has been reduced, and the functionality and speed thereof have increased. Accordingly, there is demand for a further reduction in the size and a further increase in the speed and density of semiconductor devices on which a semiconductor chip, such as an IC (integrated circuit) or an LSI (large scale integrated circuit), for such electronic devices is mounted. The reduction in the size and increase in the speed and density of semiconductor devices has resulted in an increase in power consumption, and thus the amount of heat generated per unit volume tends to increase. Therefore, in order to ensure the operational stability of semiconductor devices, a technique for improving the heat dissipation characteristics of the semiconductor devices must be employed.

A conventional semiconductor chip mounting structure is known where a semiconductor chip is flip-chip mounted by use of solder bumps, and the electrode-formed surface of the semiconductor chip is facing downward. For example, a technique shown in FIG. 9 of Japanese Patent Laid-Open Publication No. 2001-257288 is known as a technique for dissipating heat from a semiconductor device having a flip-chip mounted semiconductor chip. In this technique, a heat spreader is mounted on the rear surface of a semiconductor chip via a thermal interface material (hereinafter abbreviated as TIM) to thereby dissipate the heat generated by the semiconductor chip. However, after such a semiconductor device is mounted on a mother board, a heat dissipation member such as a heat sink, a heat pipe, or a fan must further be placed on the heat spreader.

In conventional semiconductor devices, when a heat dissipation member such as a heat sink is connected directly to the rear surface of a semiconductor chip, sufficient heat spreading characteristics cannot be obtained due to the warpage and inclination of a substrate. Therefore, as described above, a TIM and a heat spreading plate such as a heat spreader must be provided between the heat dissipation member and the semiconductor chip, causing an increase in manufacturing costs.

Furthermore, in conventional semiconductor devices, the heat dissipation member and heat spreading plate must be pressed together using high pressure in order to ensure satisfactory contact therebetween. Therefore, a problem exists in that, as the size of a semiconductor chip having an exposed rear surface increases, the semiconductor chip is more likely to be damaged.

### SUMMARY OF THE INVENTION

The present invention has been developed in view of the foregoing problems, and it is a general purpose of the invention to provide a technique for achieving improved heat dissipation characteristics in a semiconductor device at low cost.

One embodiment of the present invention relates to a semiconductor device on which a heat dissipation member can be mounted. The semiconductor device includes: a substrate; a semiconductor chip which is mounted on the substrate with a front surface of the chip facing downward; a sealing resin layer which is molded around the semiconductor chip; and a phase change portion which is provided on a rear surface of the semiconductor chip so as to be capable of being thermally connected to the heat dissipation member, melts at operating temperatures of the semiconductor chip, and has high heat conduction characteristics.

In this embodiment, when the semiconductor chip is operated with the heat dissipation member mounted thereon, the molten phase change portion deforms according to the load thereon, and as such, any warpage or inclination of the substrate is absorbed. Therefore, the heat dissipation member is securely connected to the rear surface of the semiconductor chip, and thus the heat from the semiconductor chip can be more stably spread at low cost without using a heat spreading plate such as a heat spreader.

In the above embodiment, the phase change portion may be one of: at least one low melting point metal selected from the group consisting of Ga, In, and Sn; and an alloy containing at least one of these low melting point metals.

Another embodiment of the invention relates to a method for manufacturing a semiconductor device. The method includes: flip-chip mounting a semiconductor chip on a substrate, the substrate having a wiring pattern, with a front surface of the semiconductor chip facing downward; forming a sealing resin layer around the semiconductor chip, where a rear surface of the semiconductor chip is exposed on the sealing resin layer; applying on the rear surface of the semiconductor chip a material which melts at operating temperatures of the semiconductor chip and has high heat conduction characteristics; and heating and melting the material.

According to this embodiment, a semiconductor device can be manufactured in which the heat from a semiconductor chip can be more stably spread at low cost without using a heat spreading plate such as a heat spreader.

In the above embodiment, the material may be one of: at least one low melting point metal selected from the group consisting of Ga, In, and Sn; and an alloy containing at least one of these low melting point metals.

It is to be noted that any arbitrary combination or rearrangement of the above-described structural components and so forth are all effective as and encompassed by the present embodiments. Moreover, this summary of the invention does not necessarily describe all necessary features so that the invention may also be sub-combination of these described features

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1A is a perspective view showing the schematic configuration of a semiconductor device according to an embodiment;

FIG. 1B is a cross-sectional view showing a cross-sectional structure taken along the line A-A′ in FIG. 1A;

FIG. 2 is a cross-sectional view showing in more detail the structure of a substrate of the embodiment;

FIG. 3 is a view showing a state in which a heat dissipation member is attached to the semiconductor device according to the embodiment;

FIG. 4 is a flowchart showing the outline of a method for manufacturing the semiconductor device of the embodiment;

FIGS. 5A and 5B are cross-sectional diagrams showing a process in accordance with a method for mounting a semiconductor chip of the semiconductor device of the embodiment;

FIGS. 6A to 6C are process diagrams showing a method for forming a sealing resin layer of the semiconductor device of the embodiment;

FIGS. 7A and 7B are process diagrams showing the method for forming the sealing resin layer of the semiconductor device of the embodiment; and

FIGS. 8A and 8B are process diagrams showing a method for forming a phase change portion of the semiconductor device of the embodiment.

### DETAILED DESCRIPTION OF THE INVENTION

The invention will now be described by reference to the preferred embodiments. This does not intend to limit the scope of the present invention, but to exemplify the invention.

Hereinafter, an embodiment of the present invention is described with reference to the drawings.

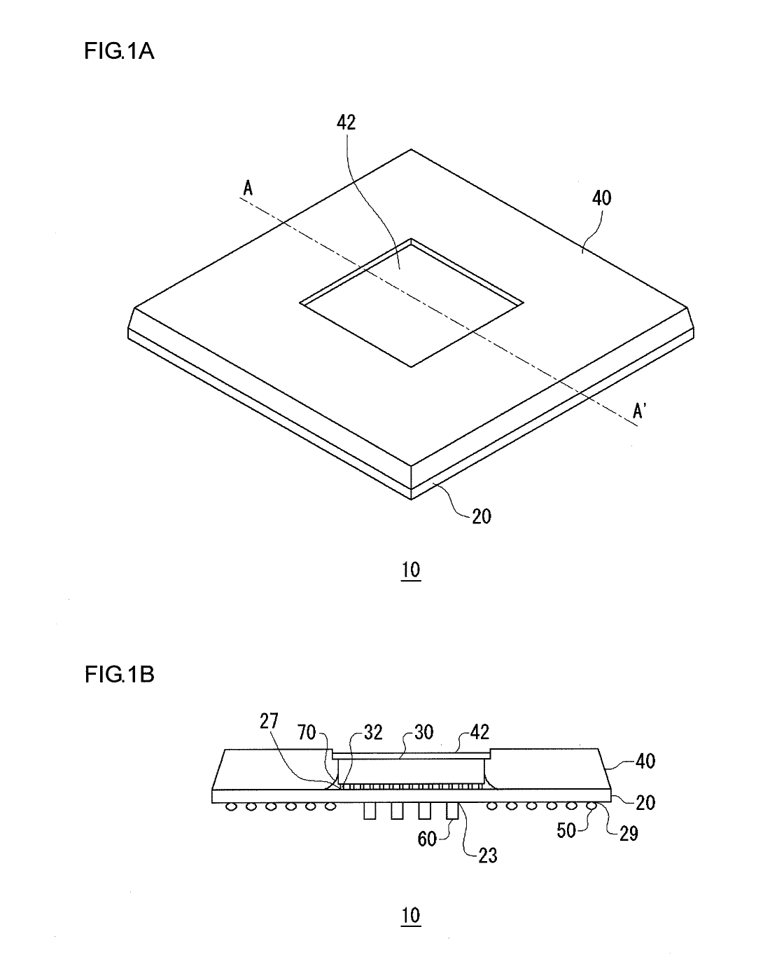

FIG. 1A is a perspective view showing the schematic configuration of a semiconductor device 10 according to the embodiment. FIG. 1B is a cross-sectional view showing a cross-sectional structure taken along the line A-A′ in FIG. 1A. The semiconductor device 10 includes: a substrate 20; a semiconductor chip 30 which is flip-chip mounted on the substrate 20 with the front surface of the chip 30 facing downward; a sealing resin layer 40 which is molded around the semiconductor chip 30; and a phase change portion 42 which is provided on the rear surface of the semiconductor chip 30 so as to be capable of being thermally connected to a heat dissipation member such as a heat sink or a heat pipe. The semiconductor device 10 of this embodiment has a BGA (Ball Grid Array) type semiconductor package structure in which a plurality of solder balls 50 is arranged in an array on the rear surface of the substrate 20.

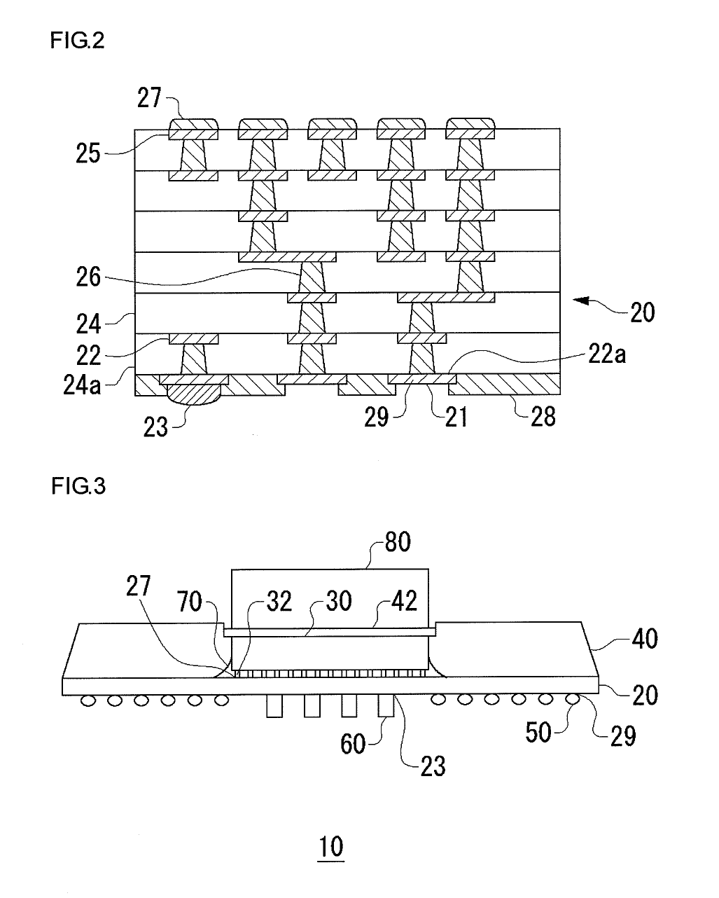

The substrate 20 of this embodiment has a multilevel interconnection structure in which interlayer insulating films and wiring layers are alternatively stacked. FIG. 2 is a cross-sectional view showing the structure of the substrate 20 in more detail. A plurality of wiring layers 22 is stacked with an interlayer insulating film 24 therebetween. Copper, for example, is employed to form the wiring layers 22. The wiring layers 22 of different levels are electrically connected by a via plug 26 provided in the interlayer insulating film 24. A solder resist film 28 composed of a resin material with excellent thermal resistance is formed around the wiring layers 22a on the rear surface of the substrate 20. Hence, the lowermost interlayer insulating film 24a is coated with the solder resist film 28 such that the solder is prevented from sticking to areas other than those areas desired when the substrate 20 is subjected to soldering. Furthermore, a plurality of ball lands 29 to which the solder balls 50 are bonded is arranged in an array on the rear surface of the substrate 20. The surface of the ball lands 29 is coated with an organic surface protection (OSP) coating material 21. Moreover, an electrode pad 23 made of Sn, Ag, or Cu, or an alloy thereof is formed in the electrode portions on which a capacitor 60 is mounted. Furthermore, a plurality of electrode pads 25 made of Ni, Pb, or Au, or an alloy thereof, formed by electrolytic plating, is arranged in an array on the front surface of the substrate 20 on which the front surface the semiconductor chip is mounted. On each of the electrode pads 25 is provided a C4 (Controlled Collapse Chip Connection) bump 27 made of tin or lead, or an alloy thereof.

As detailed above, the substrate 20 of this embodiment is a coreless substrate, and thus the thickness thereof can be reduced to, for example, approximately 300 μm in a six-layer structure. By reducing the thickness of the substrate 20, the wiring resistance is reduced, and thus an increase in the operation speed of the semiconductor device 10 can be achieved.

Returning to FIGS. 1(A) and 1(B), each of the solder balls 50 is bonded to each of the ball lands 29 provided on the rear surface of the substrate 20. Furthermore, the capacitor 60 is mounted on the electrode pads 23 provided on the rear surface of the substrate 20.

On the front surface of the substrate 20 is flip-chip mounted the semiconductor chip 30 such as an LSI with the front surface of the chip 30 facing downward. More specifically, each of solder bumps 32 serving as external electrodes of the semiconductor chip 30 is soldered to each of the C4 bumps 27 of the substrate 20. The gap between the semiconductor chip 30 and the substrate 20 is filled with an underfill 70. In this manner, the stress generated in the solder bonding portions is dispersed. Therefore, the resistance to temperature change of the semiconductor device 10 is improved, and the likelihood of warpage of the semiconductor device 10 is suppressed.

The sealing resin layer 40 is formed around the semiconductor chip 30, sealing it. In this embodiment, all the side surfaces of the semiconductor chip 30 are sealed with the sealing resin layer 40, and the height of the upper surface of the sealing resin layer 40 is greater than the height of the rear surface of the semiconductor chip 30. It is desirably that the sealing resin layer 40 cover the substrate 20 in a way where positions corresponding to positions located outside the outermost solder balls 50 of the plurality of the solder balls 50 arranged in an array are also covered. In this manner, the strength of the substrate 20 is improved through the sealing resin layer 40, and thus the likelihood of warpage of the substrate 20 is suppressed. Hence, the sealing resin layer 40 also serves as a reinforcing material of the substrate 20, and thus the strength of the entire semiconductor device 10 can be ensured even when the thickness of the substrate 20 is further reduced.

The capacitors 60 are connected within a portion of the rear surface of the substrate 20 which is located directly below the semiconductor chip 30. Hence, the wiring path from the semiconductor chip 30 to the capacitors 60 can be reduced, and as such, a reduction in wiring resistance can be achieved. In this instance, it should be appreciated that the placement position of the capacitors 60 is not limited to the portion of the rear surface of the substrate 20 which is located directly below the semiconductor chip 30. For example, the capacitors 60 may be placed in positions on the rear surface of the substrate 20 which are displaced from the positions being directly below the semiconductor chip 30, so long as the wiring path can be reduced sufficiently. Alternatively, within the range in which the wiring path can be reduced sufficiently, the capacitors 60 may be placed on the front surface of the substrate 20 and may be sealed within the sealing resin layer 40.

The phase change portion 42 is provided on the rear surface of the semiconductor chip 30. The phase change portion 42 melts at the operating temperatures of the semiconductor chip and has high heat conduction characteristics. The material used for the phase change portion 42 may be, for example, at least one low melting point metal selected from the group consisting of Ga (melting point: 29.8° C., thermal conductivity: 40.6 W/mK), In (melting point: 156.4° C., thermal conductivity: 81.6 W/mK), and Sn (melting point: 231.97° C., thermal conductivity: 66.6 W/mK) or a so-called PCMA (Phase Change Metallic Alloy) such as an alloy containing at least one of these low melting point metals. Specific examples of the alloy include In—Ag, Sn—Ag—Cu, and In—Sn—Bi.

As shown in FIG. 3, a heat dissipation member 80 such as a heat sink or a heat pipe is placed on the phase change portion 42. In this manner, the phase change portion 42 can be thermally connected to the heat dissipation member 80 without using a heat spreading plate such as a heat spreader. Specifically, when the semiconductor chip 30 is operated with the heat dissipation member 80 mounted on the phase change portion 42 and when the temperature of the semiconductor chip 30 becomes higher than the melting temperature of the phase change portion 42, the phase change portion 42 melts. When the phase change portion 42 melts, the load from the heat dissipation member 80 generates the flow of the molten phase change portion 42, and thus the molten phase change portion 42 flows from a higher load area to a lower load area. Hence, the heat dissipation member 80 is thermally connected, without gaps, to the rear surface of the semiconductor chip 30 through the phase change portion 42 having good heat conduction characteristics. Therefore, even when the substrate 20 is warped or inclined, the intimate contact between the semiconductor chip 30 and the heat dissipation member 80 is ensured through the deformation of the phase change portion 42. Thus, improved heat spreading characteristics of the semiconductor chip 30 can be obtained at low cost. Furthermore, since the heat dissipation member 80 such as a heat pipe or a heat sink can be attached at a lower pressure, any warpage or damage done to the substrate 20 due to attachment of the heat dissipation member 80 can be suppressed.

Moreover, in this embodiment, the height of the rear surface of the semiconductor chip 30 is lower than the height of the upper surface of the sealing resin layer 40 therearound, and thus the rear surface of the semiconductor chip 30 is a recessed portion. Therefore, even when the phase change portion 42 is melted during operation of the semiconductor chip 30, the phase change portion 42 is prevented from flowing away from the rear surface of the semiconductor chip 30. Hence, the phase change portion 42 can be used for a long period of time while the initial amount thereof remains unchanged.

### (Method for Manufacturing Semiconductor Device)

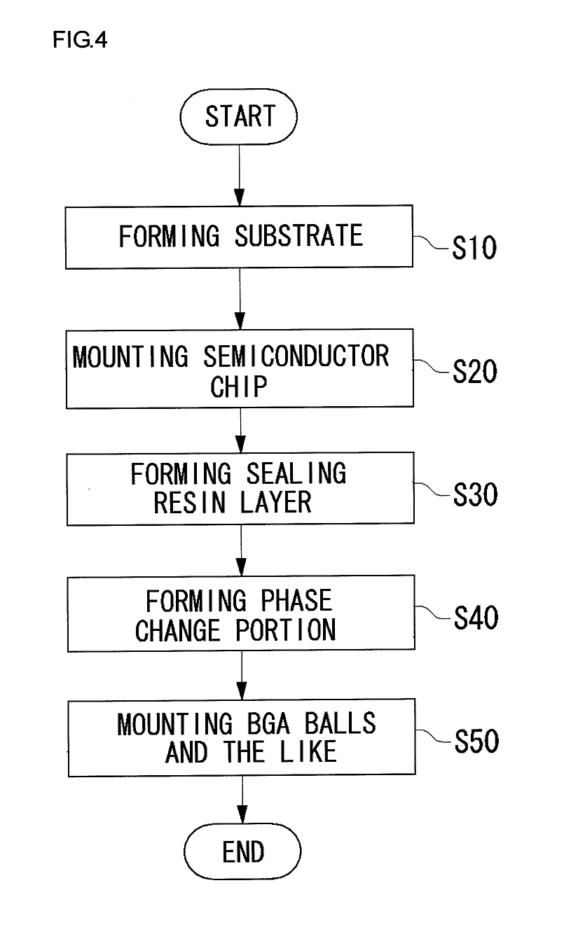

FIG. 4 is a flowchart showing the outline of a method for manufacturing the semiconductor device of the embodiment. First, a substrate having a multilevel interconnection structure is formed (S10), and a semiconductor chip is mounted on the substrate (S20). Subsequently, the semiconductor chip is sealed with a sealing resin (S30). Then, a phase change portion is formed on the rear surface of the semiconductor chip (S40). Finally, solder balls, capacitors, and the like are mounted on the rear surface of the substrate (S50).

When the substrate is formed (S10), the multilevel interconnection structure shown in FIG. 2 is formed by means of a generally used method such a damascene process. Similarly, in S50, the solder balls and capacitors may be mounted by means of a general method. Hereinafter, a detailed description is given of the method for mounting the semiconductor device (S20), the method for forming the sealing resin layer (S30), and the method for forming the phase change portion (S40).

### (1. Method for Mounting Semiconductor Chip)

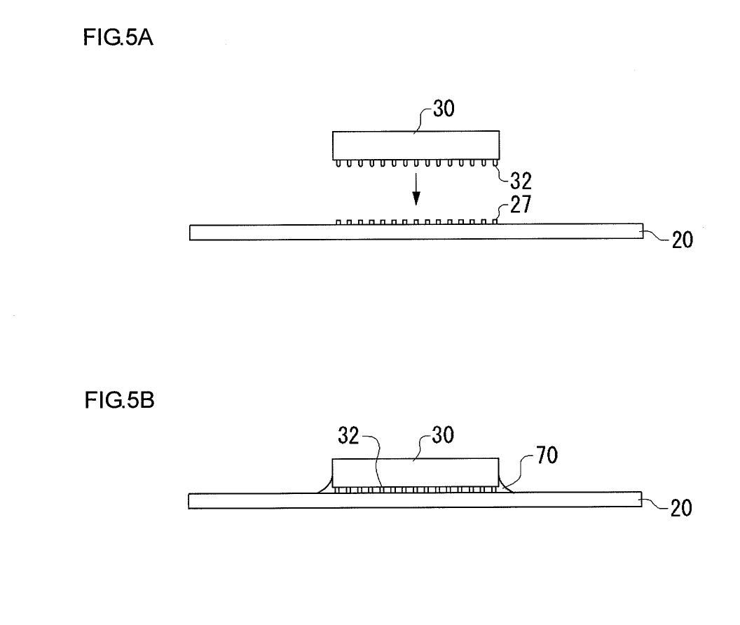

FIGS. 5A and 5B are a series of process cross-sectional diagrams showing the method for mounting the semiconductor chip 30 of the semiconductor device 10 of the embodiment.

First, as shown in FIG. 5A, each of the solder bumps 32 is soldered to the corresponding C4 bumps 27 with the external electrode terminal-mounted surface of the semiconductor chip 30 facing downward, and as such, the semiconductor chip 30 is flip-chip mounted.

Subsequently, as shown in FIG. 5B, the underfill 70 is filled into the gap between the semiconductor chip 30 and the substrate 20.

By following the above steps, the semiconductor chip 30 is flip-chip mounted on the substrate 20 with the stress generated in the solder bonding portions dispersed through the underfill 70.

### (2. Method for Forming Sealing Resin Layer)

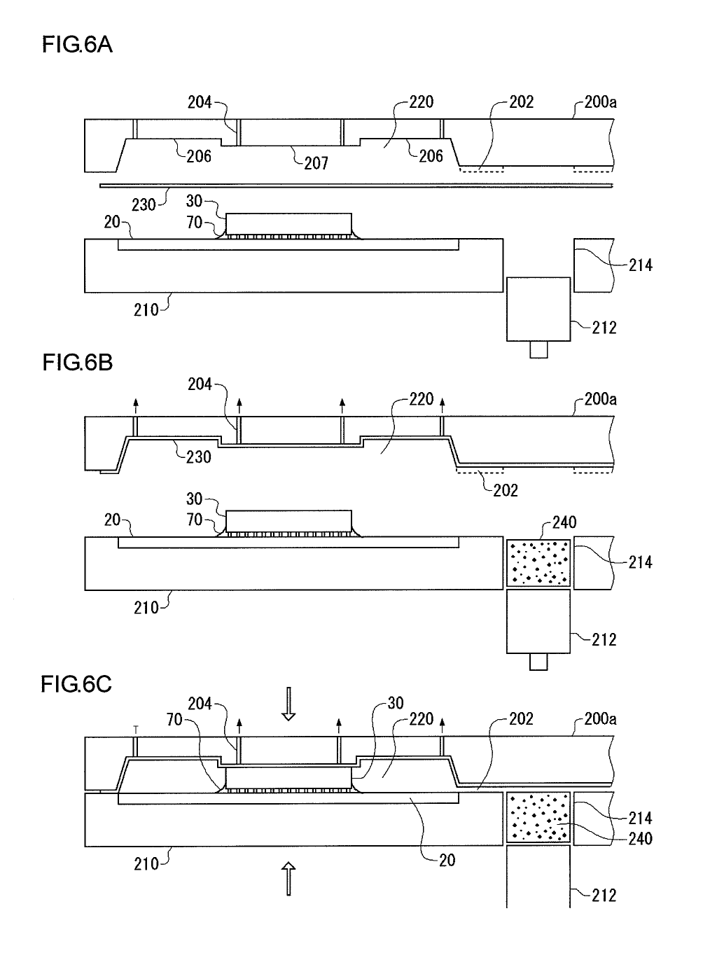

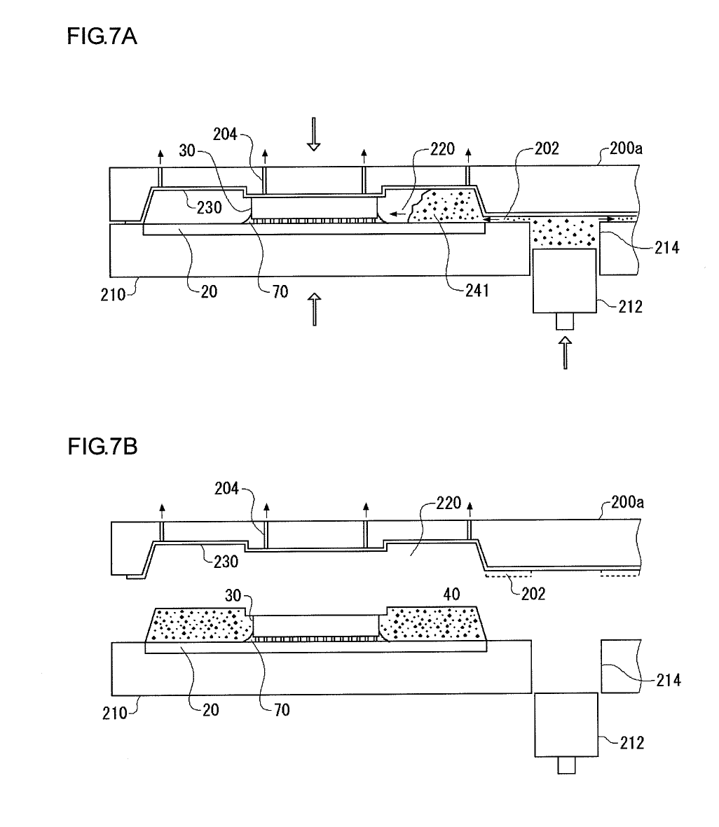

FIGS. 6A to 6C, 7A, and 7B are process diagrams showing the method for forming the sealing resin layer 40 of the semiconductor device 10 of the embodiment.

First, a description is given of the configuration of an upper mold 200a and a lower mold 210 employed in the method for forming the sealing resin layer. The upper mold 200a has a runner 202 serving as a flow passage for the molten sealing resin. The runner 202 has an opening which opens into a cavity 220 which is formed when the upper mold 200a and the lower mold 210 are brought together. The molding surface of the upper mold 200a includes: a chip-contacting surface 207 which contacts the rear surface of the semiconductor chip 30 during resin molding; and a resin-molding surface 206 which is provided for molding the sealing resin layer 40 and is located around the chip-contacting surface 207. In this embodiment, the chip-contacting surface 207 is a protruding portion protruding from the resin-molding surface 206. The chip-contacting surface 207 comes into contact with the rear surface of the semiconductor chip 30 during resin molding, and as such, the sealing resin is prevented from flowing into the gap therebetween during resin molding. Furthermore, a suction hole 204 in communication with a suction mechanism such as a pump is provided which is in the upper mold 200a. Here, the protruding portion on the upper mold is a portion protruding downward from the molding surface of the upper mold when the molding surface faces down.

Additionally, the lower mold 210 has a pot 214 in which a plunger 212 is formed so as to be reciprocally movable.

The upper mold 200a and the lower mold 210 described above are used, and the substrate 20 having the semiconductor chip 30 mounted thereon is placed on the lower mold 210 as shown in FIG. 6A. In addition to this, a release film 230 is placed between the upper mold 200a and the lower mold 210.

Next, as shown in FIG. 6B, a resin tablet 240 formed by solidifying a sealing resin is charged into the pot 214. The air between the release film 230 and the upper mold 200a is then evacuated by operating the suction mechanism to thereby bring the release film 230 into intimate contact with the upper mold 200a. As the release film 230 is employed, the sealing resin layer 40 can be molded such that a sealing resin 241 is prevented from contacting the inner surface of the cavity 220 or contacting other portions. Therefore, the upper mold 200a is not required to be cleaned, and as such, an improvement in productivity and a reduction in manufacturing cost can be achieved.

Next, as shown in FIG. 6C, the upper mold 200a and the lower mold 210 are clamped together.

Subsequently, as shown in FIG. 7A, the resin tablet 240 is heated and melted, and the plunger 212 is pressed into the pot 214 to thereby introduce the liquid sealing resin 241 in the cavity 220. After the space formed between the upper mold 200a and the substrate 20 is filled with the sealing resin 241, heating treatment is performed for a predetermined period of time to thereby solidify the sealing resin 241.

Next, as shown in FIG. 7B, the upper mold 200a is removed from the lower mold 210, and the substrate 20 having the sealing resin layer 40 formed thereon is removed.

### (3. Method for Forming Phase Change Portion)

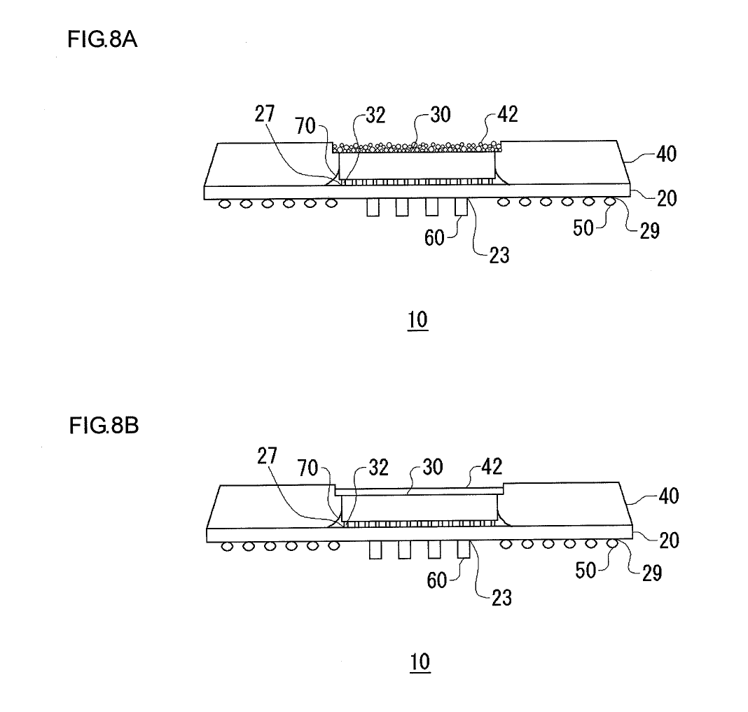

FIGS. 8A and 8B are process diagrams showing the method for forming the phase change portion 42 of the semiconductor device 10 of the embodiment.

First, as shown in FIG. 8A, the phase change portion 42 in powder form is placed on the rear surface of the semiconductor chip 30. Next, as shown in FIG. 8B, the phase change portion 42 is heated above the melting point thereof to melt the phase change portion 42. Thus, the powder particles of the phase change portion 42 are fused together, and as such, the entire rear surface of the semiconductor chip 30 is covered with the phase change portion 42.

According to the semiconductor device manufacturing method described above, a semiconductor device can be manufactured in which the heat from a semiconductor chip can be more stably spread at low cost without using a heat spreading plate such as a heat spreader.

It should be appreciated that the present invention is not limited to the embodiment described above. Various modifications such as changes in design may be made based on the knowledge of those skilled in the art, and such modified embodiments may fall within the scope of the invention.

For example, in the embodiment described above, the substrate 20 has a coreless multilevel interconnection structure. However, the technical idea of the present invention is applicable to a multilevel interconnection substrate having a core.

Furthermore, in the embodiment described above, a BGA type semiconductor package is employed, but the invention is not limited thereto. For example, a PGA (Pin Grid Array) type semiconductor package having pin-shaped lead terminals or an LGA (Land Grid Array) type semiconductor package having electrodes arranged in an array may be employed.

Moreover, the method for manufacturing the semiconductor device of the embodiment is not limited to the method in which the release film is used as described above. For example, the semiconductor device of the embodiment may be manufactured by means of a well-known transfer molding method in which a release film is not used.

What is claimed is:

1. A semiconductor device on which a heat dissipation member can be mounted, the semiconductor device comprising:
a substrate;
a semiconductor chip which is mounted on the substrate with a front surface of the chip facing downward;
a sealing resin layer which is molded around the semiconductor chip; and
a phase change portion which is provided on a rear surface of the semiconductor chip so as to be capable of being thermally connected to the heat dissipation member, melts at operating temperatures of the semiconductor chip, and has high heat conduction characteristics.

2. The semiconductor device according to claim 1, wherein the phase change portion is one of: at least one low melting point metal selected from the group consisting of Ga, In, and Sn; and an alloy containing at least one of these low melting point metals.

3. A method for manufacturing a semiconductor device, comprising:
flip-chip mounting a semiconductor chip on a substrate, the substrate having a wiring pattern, with a front surface of the semiconductor chip facing downward;
forming a sealing resin layer around the semiconductor chip, where a rear surface of the semiconductor chip is exposed on the sealing resin layer;
applying on the rear surface of the semiconductor chip a material which melts at operating temperatures of the semiconductor chip and has high heat conduction characteristics; and
heating and melting the material.

4. The method for manufacturing a semiconductor device according to claim 3, wherein the material is one of: at least one low melting point metal selected from the group consisting of Ga, In, and Sn; and an alloy containing at least one of these low melting point metals.
